(19) United States
(12) Patent Application Publication
(10) Pub. No.: US 2024/0085592 A1
(43) Pub. Date: Mar. 14, 2024

(54) METHOD OF CREATING A SURFACE PLASMON RESONANCE

(71) Applicant: OPSEC SECURITY GROUP, INC., Lancaster, PA (US)

(72) Inventors: Garry William MUDD, Nottingham (GB); Demosthenes KOUTSOGEORGIS, Nottingham (GB); Nikolaos KALFAGIANNIS, Nottingham (GB); Robert RENTON, Boston (GB); Paul DUNN, Thurcaston (GB)

(21) Appl. No.: 18/262,936

(22) PCT Filed: Jan. 28, 2022
(86) PCT No.: PCT/US2022/070393

§ 371 Date: Jul. 26, 2023

Related U.S. Application Data
(60) Provisional application No. 63/143,139, filed on Jan. 29, 2021.

(51) Int. Cl. G02B 1/12; B23K 26/00; C23C 14/20; C23C 14/58; G02B 5/00

(52) U.S. Cl. CPC G02B 1/12; B23K 26/0006; C23C 14/20; C23C 14/5813; G02B 5/008

(57) ABSTRACT

A method of creating a security product includes providing a substrate, depositing a discontinuous layer of electrically conducting material on the substrate, and laser-annealing the discontinuous layer of electrically conducting material to generate nanoparticles exhibiting a surface plasmon resonance effect.

### CROSS REFERENCE TO RELATED APPLICATION

This application claims the benefit of U.S. Provisional Patent Application Ser. No. 63/143,139, filed Jan. 29, 2021, which is incorporated by reference herein.

### BACKGROUND

### Field

The disclosed concept relates generally to a method of creating a device that utilizes a surface plasmon resonance effect. The disclosed concept also relates to anti-counterfeit products incorporating the device.

### Background Information

Anti-counterfeiting measures often utilize difficult to reproduce optical effects to verify the authenticity of products. In recent developments, complex nanostructures that exhibit surface plasmonic effects have been used. However, anti-counterfeiting measures often require both origination and replication production to generate a large volume of product. These productions can present issues with complex nanostructures.

An example of a production issue at the origination stage is that required nanoscale structures require sophisticated technologies such as electron and ion beam technologies, which can be slow and very expensive. In some cases, a physical master image is used that is then subsequently replicated. However, when a physical master image is used, it presents a risk that must be appropriately managed. Furthermore, errors in the physical master or further replication stages are propagated onto later products. Moreover, any changes to the image would require fabrication of a new master image. As an additional consideration, some techniques for creating security products, such as embossing, are well known and at risk of being used for illicit replication.

These issues and challenges are prevalent in the development of security products for verifying the authenticity of products. There is an ever present challenge to develop new techniques that address or eliminate the issues with origination and replication, while being fast and cost-effective to produce as well as being difficult to replicate by illicit actors.

There is continuous room for improvement in anti-counterfeiting measures.

### SUMMARY

In accordance with aspects of the disclosed concept, a method of creating a security product comprises: providing a substrate; depositing a discontinuous layer of electrically conducting material on the substrate; and laser-annealing the discontinuous layer of electrically conducting material to generate nanoparticles exhibiting a surface plasmon resonance effect.

### BRIEF DESCRIPTION OF THE DRAWINGS

A full understanding of the disclosed concept can be gained from the following description of the preferred embodiments when read in conjunction with the accompanying drawings in which:

FIGS. 1A-ID depict various stages of creating a security product that utilizes a surface plasmon resonance effect in accordance with an example embodiment of the disclosed concept;

FIG. 2 is a flowchart of a method of creating a security product that utilizes a surface plasmon resonance effect in accordance with an example embodiment of the disclosed concept;

FIG. 3 illustrates a discontinuous layer of electrically conductive material before and after laser-annealing in accordance with an example embodiment of the disclosed concept;

FIG. 4 illustrates nanoparticles after laser-annealing with one laser pulse in accordance with an example embodiment of the disclosed concept;

FIG. 5 illustrates nanoparticles after laser-annealing with two laser pulses in accordance with an example embodiment of the disclosed concept;

FIG. 6 illustrates nanoparticles after laser-annealing with 150 laser pulses in accordance with an example embodiment of the disclosed concept;

FIG. 7 is a conceptual diagram showing nanoparticles becoming partially or fully submerged within the substrate from laser-annealing in accordance with an example embodiment of the disclosed concept; and

FIG. 8 is a conceptual diagram showing the effect of fully and/or partially submerged nanoparticles on optical effects in accordance with an example embodiment of the disclosed concept.

### DESCRIPTION OF THE PREFERRED EMBODIMENTS

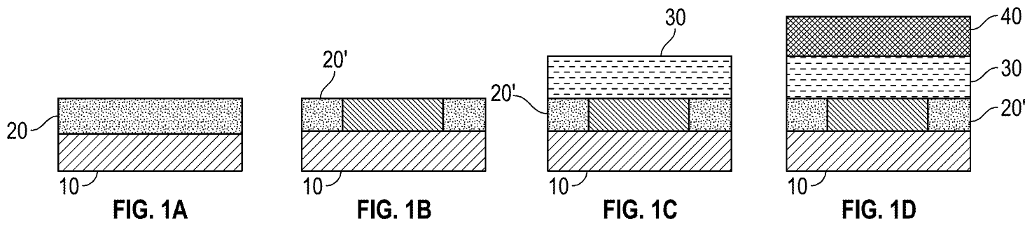

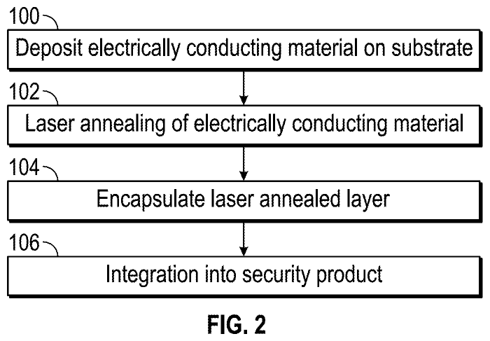

FIGS. 1A-1D depict various stages of creating a security product that utilizes a surface plasmon resonance effect in accordance with an example embodiment of the disclosed concept and FIG. 2 is a flowchart of a method of creating a security product that utilizes a surface plasmon resonance effect in accordance with an example embodiment of the disclosed concept.

FIG. 1A illustrates a substrate 10 and a thin layer of discontinuous electrically conducting material 20. In some example embodiments, the substrate 10 is composed of polycarbonate. For example, the substrate 10 may be a security-grade formulation of polycarbonate. In some example embodiments, the substrate 10 may be about 50 microns thick. The substrate 10 may also be transparent and/or flexible. It will be appreciated that the substrate 10 may also be composed of other materials without departing from the scope of the disclosed concept. The other materials may include, without limitation, other polymers such as, without limitation, polyethylene terephthalate (PET) or polyethylene terephthalate glycol (PETG), polyamides/nylon, polypropylene (PP), cellophane, and paper or hybrid paper/polymer substrates used for bank notes. It will also be appreciated that the thickness of the substrate 10 may be varied without departing from the scope of the disclosed concept. In some example embodiments, the thickness may be within a range of about 25 μm to about 100 μm, but it will be appreciated that other thicknesses may be employed without departing from the scope of the disclosed concept. In some example embodiments, the substrate 10 may be rigid and/or opaque.

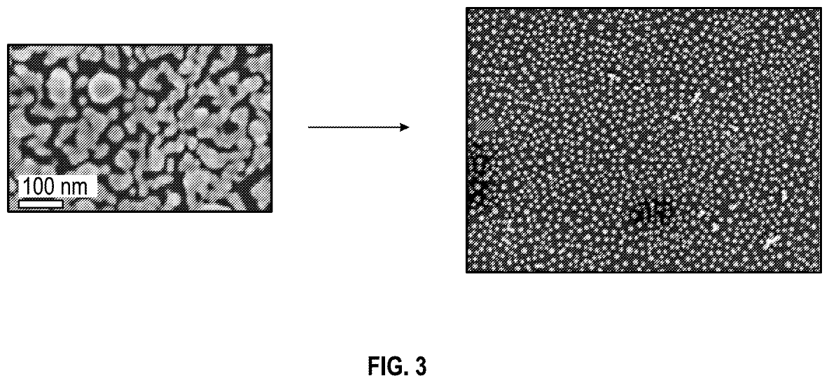

The thin layer of discontinuous electrically conducting material 20 is deposited on top of the substrate 10. An image of an example thin layer of discontinuous electrically conducting material is shown in the left image of FIG. 3. In the example shown in FIG. 3, the electrically conducting material has an “islands and rivers” morphology. The layer is discontinuous in that there are gaps in the layer of electrically conducting material, as opposed to a continuous layer in which such gaps are not present. In some example embodiments of the disclosed concept, the gaps in the layer are not filled with any specific material during the deposition process, but are instead left to be filled by ambient conditions (i.e., by a vacuum during vacuum deposition, by air when exposed to ambient conditions, etc.).

The electrically conducting material in some example embodiments of the disclosed concept is silver. However, it will be appreciated that other materials may be employed such as, without limitation, other metals like gold, aluminium or copper, as well as some metal oxides. It will be appreciated that semi-metals or semi-conductors may also be employed in some example embodiments. It will also be appreciated that alloys and composites may be employed in some example embodiments. For example and without limitation, alloying or doping silver with other metals may shift the spectral window more towards red or blue visible colors. The choice of material will generally determine the spectral region of the plasmonic response (i.e. visible, infrared or ultra-violet). In some embodiments, the thin layer of discontinuous electrically conducting material 20 has a thickness of less than about 100 nm. In some embodiments, the thin layer of discontinuous electrically conducting material 20 has a thickness of less than about 50 nm. In an example embodiment where the electrically conducting material is silver, the thin layer of discontinuous electrically conducting material 20 has a thickness in a range of about 4-16 nm. In some example embodiments, the discontinuous electrically conducting material 20 has a thickness of greater than about 100 nm.

The thin layer of discontinuous electrically conducting material 20 may be formed by depositing the electrically conducting material onto the substrate 10. In some example embodiments, the electrically conducting material is deposited on the substrate using a vacuum deposition technique such as thermal evaporation or magnetron sputtering, which can be in batch or roll-to-roll format. However, it will be appreciated that the thin layer of discontinuous electrically conducting material 20 may be formed using other processes such as, for example and without limitation, printing from an ink, solution-based deposition, sol-gels, or other processes.

FIG. 1B depicts a laser-annealed thin layer of discontinuous electrically conducting material 20′. In some example embodiments of the disclosed concept, laser radiation from an KrF/ArF Excimer or a Nd-doped solid-state laser with harmonics can be used to perform laser-annealing of the thin layer of discontinuous electrically conducting material 20 and to generate a nanoparticle distribution that exhibits a plasmonic response. In an example embodiment, a KrF Excimer laser with a wavelength of 248 nm is employed for the laser-annealing process. In another example embodiment, a Nd-doped solid-state laser with a 266 nm wavelength harmonic is employed for the laser-annealing process. It will be appreciated that other lasers and wavelengths (e.g., without limitation, 193 nm (Excimer), 248 nm (Excimer), 266 nm (solid state), 355 nm (solid state), 532 nm (solid state), 1064 nm (solid state), 308 nm (XeCl Excimer), etc.) may also be employed for the laser-annealing process without departing from the scope of the disclosed concept. While some examples of lasers used for laser-annealing have been provided, it will be appreciated that the disclosed concept is not limited to these examples, and other lasers such as, without limitation, fiber lasers, disc lasers, and other gas lasers, may be employed without departing from the scope of the disclosed concept.

In an example embodiment, the beam energy distribution profile used in the laser-annealing process is a spatially-uniform distribution (“top-hat”). In another example embodiment, the beam energy distribution profile used in the laser-annealing process is a M²/Gaussian-like distribution. The shape of the energy profile of the beam can be manipulated using custom beam shaping optics and there are a broad range of configurations that are achievable. While “top-hat” and gaussian profiles are two examples, it will be appreciated that other beam profiles may be employed in the laser-annealing process without departing from the scope of the disclosed concept.

Laser-annealing the thin layer of discontinuous electrically conducting material 20 induces the formation of nanoparticle distributions that generate plasmonic optical effects. Parameters of the process may be controlled to create the desired optical effect.

One of the benefits of forming plasmonic nanoparticles using laser-annealing is the flexibility provided by a digitally controlled laser scanning system. Such an approach can be operated without physical templates/masks (photolithography) or master images (embossing) with the image resolution determined by the size of the laser beam used to induce the annealing. The digital control also enables complete customizability of plasmonic image artwork and for the integration of custom data, barcoding and serialization into each individual plasmonic image within a single laser-annealing process. Such custom data can be linked digitally to information in a database enabling product or production-line track and trace, with the readable and identifiable marks having plasmonic optical characteristics, adding an additional barrier to the illicit replication of such data.

Various optical components are available for either expansion of the beam to large areas (e.g., without limitation, 130 mm×130 mm), as well as for creating beam widths on the micron scale (˜25 microns beam waist). In some example embodiments, the laser-annealing process takes place in the order of nanoseconds (7-25 ns pulse duration), regardless of the size of the beam. However, it will be appreciated that shorter or longer pulse durations may be employed without departing from the scope of the disclosed concept. It will be appreciated that there is a trade-off between the scanning speed and the resolution, with high-resolution features requiring a small beam size and a slower scanning speed to fill the equivalent area in comparison to a low-resolution fill using a larger beam size as more image area can be annealed per unit time (in some systems the time required to generate the next laser pulse of sufficient energy can range from 1-50 Hz on Excimer systems and 1-120 kHz on solid state systems, but it will be appreciated that such times may vary based on the system used).

FIG. 1C depicts an encapsulation layer 30 disposed over the laser-annealed thin layer of discontinuous electrically conducting material 20′. It will be appreciated that in example embodiments of the disclosed concept, the encapsulation layer 30 is added after the laser-annealing process. It will also be appreciated that the encapsulation layer 30 may be omitted without departing from the scope of the disclosed concept. However, the encapsulation layer 30 serves to protect the laser-annealed thin layer of discontinuous electrically conducting material 20′ and, in some example embodiments, is integral to achieving a desired plasmonic response.

In some example embodiments, the encapsulation layer 30 is a polymer lamination that provides a protective hard-coat for the laser-annealed thin layer of discontinuous electrically conducting material 20′. The polymer lamination may, depending upon the nature of laminating polymer chosen, also induce a small red-shift in the spectral characteristics of the plasmonic response. The red-shift in the plasmonic response increases with the refractive index of the material used in the encapsulation layer 30. This effect should be accounted for in the design process, and, in some example embodiments is used to achieve particular effects. For example, in some example embodiments, high refractive index materials are used in the encapsulation layer to achieve a plasmonic response that would otherwise be difficult to realize just through choice of material and laser-annealing parameters alone (i.e. intentional use of a dielectric to red-shift the plasmonic response). It will be appreciated that the encapsulation layer 30 is not limited to polymer materials and may use any other suitable materials. In an example embodiment, the encapsulation layer 30 may be composed of zinc sulphide that acts as a high refractive index layer. The zinc sulfide may be top coated with a polymer. However, this is just an example of materials that may be employed, and other suitable materials may be employed without departing from the scope of the disclosed concept.

In some example embodiments, additional layers composed of dielectric material may be disposed above and below the laser-annealed thin layer of discontinuous electrically conducting material 20′. Such a construct leads to different optical results (i.e. distinct colors are observable when viewing the front-side reflective mode, the rear-side reflective mode, and the transmissive mode when fabricated on a transparent substrate). In some example embodiments, the deposition of some of the dielectric layers may be done before the deposition of the thin layer of electrically conducting material 20. However, the encapsulation layer 30 would still be deposited after laser-annealing, with the annealing of the thin layer of electrically conducting material 20 taking place open to the surrounding environment.

In some example embodiments, a first dielectric layer may be deposited and patterned using a lithographic technique (either removing or masking sections of the first dielectric layer) and a second dielectric with a different refractive index may also then be deposited, resulting in a contrasting pattern of different dielectrics with differing refractive indexes (e.g., a checkerboard or stripe pattern, etc.). Forming laser-annealed nanoparticles atop such a surface will result in two different plasmonic responses for the same laser-annealing condition, with the nanoparticles on (or submerged within) the dielectric of higher refractive index red-shifted more than the other. The dielectric layers may instead be polymer layers with differing refractive indexes.

FIG. 1D depicts an example of additional layers 40 that may be included when integrating the laser-annealed thin layer of discontinuous electrically conducting material 20′ into a security product. However, it will be appreciated that the additional layers 40 may be omitted without departing from the scope of the disclosed concept. The additional layers 40 may, for example and without limitation, provide other optical or security effects. It will also be appreciated that the location of additional layers 40 may be varied. For example, one or more additional layers 40 may be disposed below the substrate 10 without departing from the scope of the disclosed concept.

Additional features may be incorporated into the security product in accordance with various example embodiments of the disclosed concept. For example, in some embodiments, optical spacer layers may be employed that act to modify the absorption of light and the thermal characteristics of the combined structure to influence the laser-annealing process. The optical spacer layers could take the form of silicon or aluminium oxide layers (or others, or combinations of these and/or others) being deposited prior to the thin layer for laser-annealing. Some other non-limiting examples of materials that may be used for the optical spacer layers includes TiO₂, ZnO, and MgF₂. However, it will be appreciated that this is a non-exhaustive list of examples, and other materials may be employed without departing from the scope of the disclosed concept.

Another example of an additional feature is a covert effect. The laser-annealing method is compatible with materials that generate a plasmonic response in the infra-red (e.g. copper nanoparticles) or the ultra-violet (e.g. aluminium nanoparticles). Use of such materials can be used to generate covert security effects that are not visible. These hidden features would be observable with the use of appropriate illumination (e.g. sunlight or IR or UV lamps) and a reading tool (e.g. an IR or a UV camera) for inspection. In some example embodiments, covert and overt plasmonic features may be created during a single-phase of laser-annealing, i.e. generating overt and covert plasmonic optical effects in registration. The creation of the covert features may also be customizable and/or personalized.

The laser-annealed thin layer of discontinuous electrically conducting material 20′ alone, or in combination with the encapsulation layer 30 and or additional features, may provide, in an example embodiment, a zero-order reflection transmission color-switch effect. In the simplest format, a single layer of plasmonic metal clusters on a visibly transparent polymer substrate, a visible color-switch can be observed between direct reflection and transmission (e.g. blue-to-yellow). The choice of colors of the switch may be determined by the laser-annealing parameters and are fixed after the laser-annealing process is completed. The color-switch may also be modified by the encapsulation layer 30.

The optical effect provided by the laser-annealed thin layer of discontinuous electrically conducting material 20′ may be integrated with additional optical technologies in the final product. For example, the optical effect provided by the laser-annealed thin layer of discontinuous electrically conducting material 20′ may be placed side-by-side with other optical effects. For example, the side-by-side optical effects may produce an enhanced contrasting effect and serve authentication purposes (i.e. harder to counterfeit multiple technologies, harder to tamper without damaging multiple technologies, harder to align/realign in good registration).

As other examples, the optical effect provided by the laser-annealed thin layer of discontinuous electrically conducting material 20′ may be integrated with microstructures such as micromirrors, diffractive elements, etc., that provide kinetic effects, or other structures that provide enhancement or amplification of the visual impact of plasmonic particles. For example, liquid crystals, dielectric and/or metal thin layers and optical stacks, methods of inducing polarization, and other variants of plasmonic nanostructures (e.g. nano-hole arrays) may be employed to provide enhancement or amplification of the visual impact of plasmonic particles.

It will be appreciated that that the security product has a range of applications such as, without limitation, government issued documents (e.g., ID cards, passports, tax stamps, etc.), currency (banknotes, transaction cards, etc.), and other applications (bottles, blister packs, microelectronics, direct-to-product, supply chain down-line applications, etc.).

The steps shown in the flowchart of FIG. 2 correspond to the various stages depicted in FIGS. 1A-1D. For example, at 100, an electrically conducting material is deposited onto a substrate, as is shown in FIG. 1A. At 102, laser-annealing of the electrically conducting material is performed, as is shown in FIG. 1B. At 104, the laser-annealed layer is encapsulated, as is shown in FIG. 1C. And at 106, integration into a security product is performed, as is shown in FIG. 1D. It will be appreciated that steps 104 and 106 may be omitted without departing from the scope of the disclosed concept.

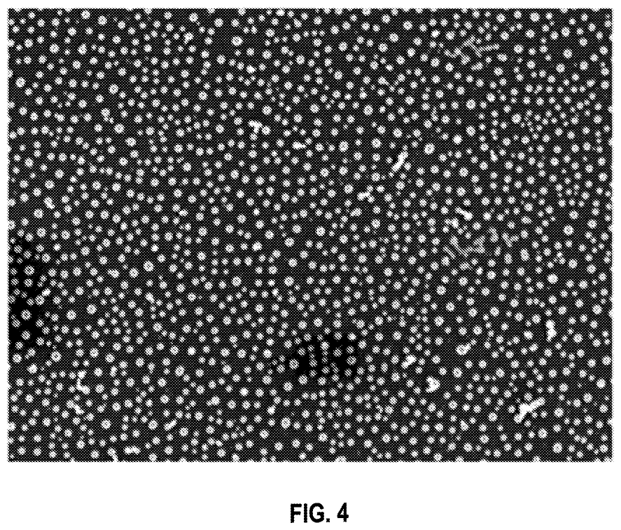

FIGS. 3-8 depict an effect of the laser-annealing process in some example embodiments of the disclosed concept where a polymer substrate, as opposed to silicon, is employed, which will be described hereinafter. FIG. 3 includes images of a thin layer of discontinuous electrically conducting material in the left image and laser-annealed nanoparticles after one laser pulse in the right image. The image on the left is shown at a 100 nm scale and the image on the right is shown at a 1000 nm scale. FIG. 4, similarly, is an image of the laser-annealed nanoparticles after one laser pulse. As shown in FIG. 4, the nanoparticles, shown in white, sit on the polymer substrate, shown in black.

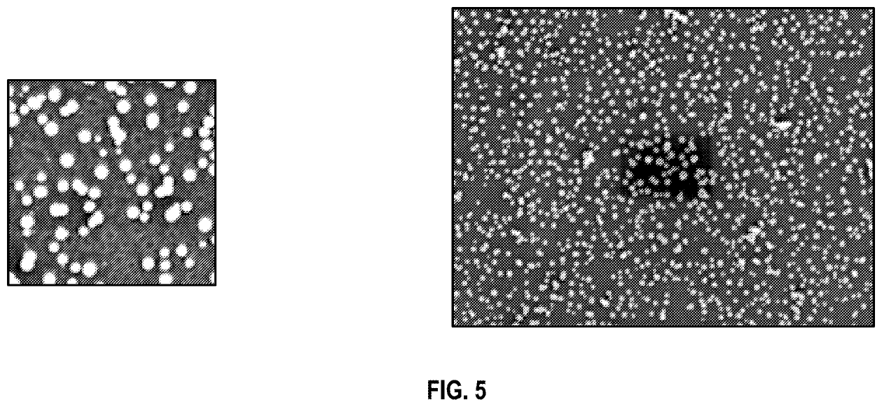

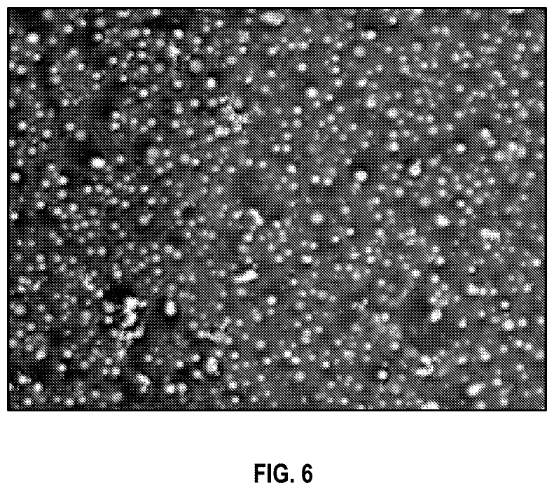

FIG. 5 includes images of nanoparticles after laser-annealing with two laser pulses. The image on the left is a zoomed in portion of the image on the right. After two laser pulses, there is evidence that some nanoparticles have been removed from the surface, leaving behind a nanoscale indentation in the polymer substrate. FIG. 6 includes an image of nanoparticles after laser-annealing with 150 laser pulses. With this many laser pulses, it becomes apparent that the nanoparticle distributions are becoming partially and/or fully submerged within the substrate.

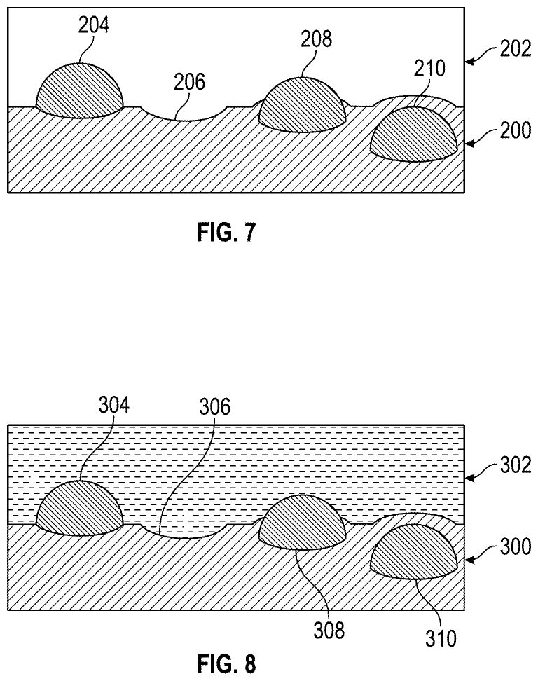

FIG. 7 is a schematic diagram that illustrates the nanoparticles 204,208,210 submerging into the substrate 200 as well as a site 206 where a nanoparticle has been removed during the laser-annealing process. The ambient environment 202 is above the substrate 200 in FIG. 7. As the number of laser pulses increases, a greater proportion of the remaining nanoparticles 204,208,210 become partially or fully submerged within the substrate 200. FIG. 7 shows various states of submersion, with nanoparticle 204 having little submersion into the substrate 200, nanoparticle 208 being partially submerged, and nanoparticle 210 being fully submerged. Submersion is an effect produced in some example embodiments of the disclosed concept where a polymer substrate (such as polycarbonate) is employed. While the effect may occur in other types of substrates, such as glass substrate, a polymer substrate is advantageous due to its flexibility and compatibility with high-volume manufacturing in roll-to-roll products. Glass would be brittle, shatter, and be harder to handle in high-volume manufacturing. Moreover, polymer substrate is typically a preferable medium for anti-counterfeiting products due in part to its flexibility.

FIG. 8 is a schematic diagram that illustrates an encapsulation layer 302 disposed over nanoparticles 304,308,310 in various stages of submersion in the substrate 300 as well as a site 306 where a nanoparticle has been removed during the laser-annealing process. As noted previously, the encapsulation layer red-shifts the plasmonic optical effect of the nanoparticles 304,308,310. However, the magnitude in the red-shift of the plasmonic response induced by an encapsulating layer 302 will be proportional to the percentage of the nanoparticle distribution that has become submerged in the substrate by the laser-annealing stage. A structure with a low population of submerged nanoparticles will experience a greater red-shift of the plasmonic response following encapsulation, in comparison to a structure with a high population of submerged nanoparticles, which will experience little-to-no shift in the plasmonic response. Additionally, when the nanoparticles are fully submerged and enveloped by the substrate, the substrate will protect the nanoparticles and separate encapsulation for protection purposes may be omitted. When creating a security product, the proportion of nanoparticles submerged in the substrate may be controlled to produce a desired effect. As such, the choice of polycarbonate polymer, and specific combinations of laser-annealing parameters such as choice of laser, pulse profile and pulse number, power and duration, separately or collectively, as well as any additional features, such as encapsulation, optical spacers, and other additional features, serve to produce the desired final structure of the product.

It will be appreciated that the use of a polymer substrate and the process of laser-annealing a layer of electrically conducting material such that at least some of the produced nanoparticles become at least partially submerged into the substrate may be employed in various embodiments of the disclosed concept.

It will be appreciated that in some example embodiments of the disclosed concept, the electrically conducting material is laser annealed such that at least some of the nanoparticles become at least partially submerged within the substrate. It will be appreciated that the proportion of nanoparticles that become at least partially submerged within the substrate may be varied without departing from the scope of the disclosed concept. In an example embodiment, at least about 10% of the nanoparticles become at least partially submerged within the substrate. In another example embodiment, at least about 25% of the nanoparticles become at least partially submerged within the substrate. In another example embodiment, at least about 50% of the nanoparticles become at least partially submerged within the substrate. In another example embodiment, at least about 75% of the nanoparticles become at least partially submerged within the substrate. In another example embodiment, between about 25% and about 75% of the nanoparticles become at least partially submerged within the substrate. It will also be appreciated that at least partially submerged nanoparticles includes both partially submerged and fully submerged nanoparticles.

While specific embodiments of the disclosed concept have been described in detail, it will be appreciated by those skilled in the art that various modifications and alternatives to those details could be developed in light of the overall teachings of the disclosure. Accordingly, the particular arrangements disclosed are meant to be illustrative only and not limiting as to the scope of the disclosed concept which is to be given the fill breadth of the claims appended and any and all equivalents thereof.

1. A method of creating a security product, the method comprising:
providing a substrate;
depositing a discontinuous layer of electrically conducting material on the substrate; and
laser-annealing the discontinuous layer of electrically conducting material to generate nanoparticles exhibiting a surface plasmon resonance effect.

2. The method of claim 1, wherein the substrate is composed of a polymer material.

3. The method of claim 1, wherein the substrate has a thickness within a range of about 25 μm to about 100 μm.

4. The method of claim 1, wherein the discontinuous layer of electrically conducting material includes at least one of silver, gold, copper, and aluminum.

5. The method of claim 1, wherein the discontinuous layer of electrically conducting material has a thickness of less than about 100 nm.

6. The method of claim 1, wherein the discontinuous layer of electrically conducting material is deposited using vacuum deposition.

7. The method of claim 1, wherein the discontinuous layer of electrically conducting material is laser-annealed using an Excimer or solid-state laser.

8. The method of claim 1, further comprising:
depositing an encapsulation layer onto the laser-annealed discontinuous layer of electrically conducting material.

9. The method of claim 8, wherein the encapsulation layer is composed of a polymer material and provides a protective hard-coat for the laser-annealed discontinuous layer of electrically conducting material.

10. The method of claim 1, further comprising:
depositing at least one additional layer on the substrate.

11. The method of claim 10, wherein the at least one additional layer includes a first dielectric layer having a first refractive index and a second dielectric layer having a second refractive index, wherein the first refractive index and the second refractive index are different.

12. The method of claim 1, wherein laser-annealing the electrically conducting material to generate nanoparticles exhibiting a surface plasmon resonance effect includes laser-annealing the electrically conducting material such that at least some of the nanoparticles become at least partially submerged within the substrate.

13. The method of claim 12, wherein laser-annealing the electrically conducting material to generate nanoparticles exhibiting a surface plasmon resonance effect includes laser-annealing the electrically conducting material such that at least some of the nanoparticles become fully submerged within the substrate.

14. The method of claim 1, wherein the security product exhibits a plasmonic response in infra-red or ultra-violet spectrum.

15. A security product created by the method of claim 1.
